(19) United States
(12) Patent Application Publication
(10) Pub. No.: US 2009/0229668 A1
(43) Pub. Date: Sep. 17, 2009

(54) Organic photoelectric conversion film and photoelectric conversion device having the same

(76) Inventors: Kyu-Sik Kim, Yongin-si (KR); Sang-Cheol Park, Yongin-si (KR); Jung-Gyu Nam, Yongin-si (KR); Masahiro Hiramoto, Osaka (JP)

Correspondence Address: CANTOR COLBURN, LLP, 20 Church Street, 22nd Floor, Hartford, CT, 06103, US

(21) Appl. No.: 12/153,887

(22) Filed: May 27, 2008

(30) Foreign Application Priority Data
Mar. 11, 2008 (KR) 1020080022605

(51) Int. Cl. H01L 51/46

(52) U.S. Cl. 136/263; 977/948

(57) ABSTRACT

Provided are an organic photoelectric conversion film and a photoelectric conversion device having the organic photoelectric conversion film. The organic photoelectric conversion film includes a p-type substance layer including rubrene and an n-type substance layer formed on the p-type substance layer and including fullerene or fullerene derivative.

### CROSS-REFERENCE TO RELATED PATENT APPLICATIONS AND CLAIM OF PRIORITY

This application claims the benefit of Korean Patent Application No. 10-2008-0022605, filed on Mar. 11, 2008, in the Korean Intellectual Property Office, the disclosure of which is incorporated herein in its entirety by reference.

### BACKGROUND OF THE INVENTION

1. Field of the Invention

The present invention relates to an organic photoelectric conversion film and a photoelectric conversion device having the same, and more particularly, to an organic photoelectric conversion film that produce current by selectively absorbing the wavelength of a blue light ray, and a photoelectric conversion device having the organic photoelectric conversion film. 2. Description of the Related Art

In general, a photoelectric conversion device converts light to an electric signal using a photoelectric effect. The photoelectric conversion device is widely used for various optical sensors for automobiles or home, or solar batteries, in particular for complementary metal-oxide-semiconductor (CMOS) image sensors.

Conventionally, a photoelectric conversion film formed of an inorganic material is mainly used in the photoelectric conversion device. However, since the inorganic photoelectric conversion film exhibits an inferior selectivity according to the wavelength of light, a CMOS image sensor using the inorganic photoelectric conversion film needs a color filter that decomposes incident light into red light, green light, and blue light. However, the use of the color filter generates a Moire defect, and an optical low pass filter used to address the defect may cause the degradation of resolution. Thus, a study to manufacture a photoelectric conversion film using an organic material is recently performed.

Meanwhile, the color filter, a microlens, and a photodiode have been used as the photoelectric conversion device for the conventional CMOS image sensor. There are problems in that the color filter generates a Moire defect and the microlens reduces light arriving at the photodiode. Thus, to address the problems, the development of a photoelectric conversion device of a CMOS image sensor having a new structure without using the color filter, microlens, or photodiode is needed.

### SUMMARY OF THE INVENTION

To solve the above and/or other problems, the present invention provides an organic photoelectric conversion film producing current by selectively absorbing the wavelength of a blue light ray and a photoelectric conversion device having the organic photoelectric conversion film.

According to an aspect of the present invention, an organic photoelectric conversion film comprises a p-type substance layer including rubrene, and an n-type substance layer formed on the p-type substance layer and including fullerene or fullerene derivative.

The organic photoelectric conversion film may further comprise a co-deposition layer formed between the p-type substance layer and the n-type substance layer.

The co-deposition layer may be formed by co-depositing rubrene and said at least one material

C60 fullerene may be used as the fullerene.

Each of the p-type and n-type substance layers may have a thickness of 5 to 300 nm.

The organic photoelectric conversion film is capable of generating current by selectively absorbing the wavelength of a blue light ray.

According to another aspect of the present invention, a photoelectric conversion device comprises an anode and a cathode separated a predetermined distance from each other, and an organic photoelectric conversion film formed between the anode and the cathode, wherein the organic photoelectric conversion film comprises a p-type substance layer formed on the anode and including rubrene, and an n-type substance layer formed on the p-type substance layer and including fullerene or fullerene derivative.

The photoelectric conversion device may further comprise a hole blocking layer which is formed between the cathode and the n-type substance layer.

The hole blocking layer may be formed of NTCDA.

The hole blocking layer may have a thickness of 10 to 1,000 nm.

The photoelectric conversion device may further comprise an electron blocking layer which is formed between the anode and the p-type substance layer.

The anode may be formed of a transparent conductive material.

The cathode may be formed of a transparent conductive material or metal.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a photoelectric conversion device according to an embodiment of the present invention;

FIG. 2 is a cross-sectional view of a photoelectric conversion device according to another embodiment of the present invention;

FIG. 3 is a plot showing the absorption spectrum of an organic photoelectric conversion film in the photoelectric conversion device according to an embodiment of the present invention; and

FIG. 4 is a plot showing a photocurrent density according to the wavelength of light in the photoelectric conversion device according to an embodiment of the present invention.

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

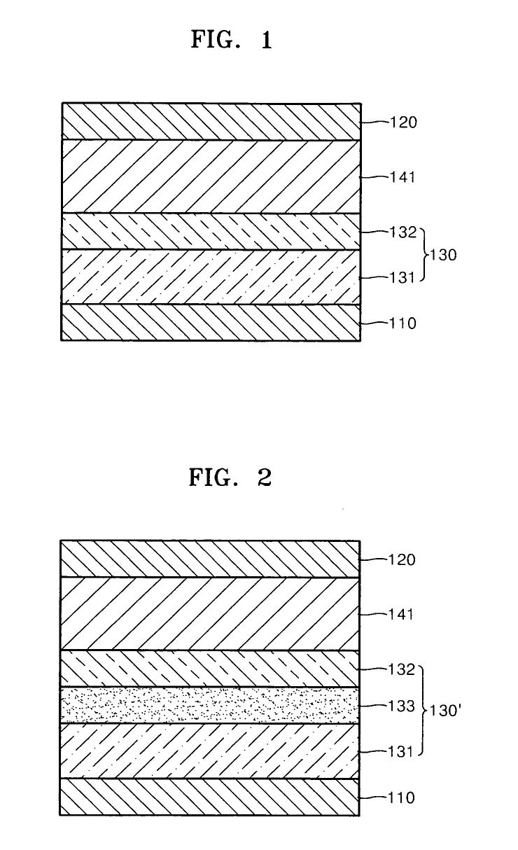

FIG. 1 is a cross-sectional view of a photoelectric conversion device according to an embodiment of the present invention. Referring to FIG. 1, a photoelectric conversion device according to the present embodiment includes an anode 110, a cathode 120, and an organic photoelectric conversion film 130 that is formed between the anode 110 and the cathode 120.

The anode 110 may be formed on a transparent substrate (not shown) formed of glass or plastic. The anode 110 may be formed of a transparent conductive material such as ITO (indium tin oxide). The cathode 120 may be formed of metal such as Ag, Al, or Au, or the transparent conductive material such as ITO. However, the present invention is not limited thereto.

The organic photoelectric conversion film 130 converts light to an electric signal using a photoelectric effect. The organic photoelectric conversion film 130 includes a p-type substance layer 131 formed on the anode 110 and an n-type substance layer 132 formed on the p-type substance layer 131. In the present embodiment, rubrene is used as the p-type substance and fullerene or a fullerene derivative is used as the n-type substance. Here, C60 fullerene may be used as the fullerene. C70 fullerene, C76 fullerene, C78 fullerene, or C80 fullerene, for example, may be used as the fullerene derivative. However, the present invention is not limited thereto.

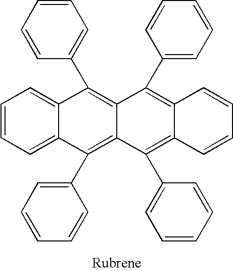

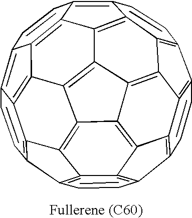

The organic photoelectric conversion film 130 may be formed by sequentially depositing rubrene that is the p-type substance and fullerene or fullerene derivative that is the n-type substance. Each of the p-type substance layer 131 and the n-type substance layer 132 may be formed to have a thickness of 5 to 300 nm, more preferably, 5 to 100 nm. In the present embodiment, the organic photoelectric conversion film 130 has a p-n junction structure of the p-type substance layer 131 including rubrene and the n-type substance layer 132 including fullerene or fullerene derivative.

A hole blocking layer 141 may be formed between the cathode 120 and the n-type substance layer 132. The hole blocking layer 141 works as a protection layer to simultaneously prevent the movement of holes and short circuit. The hole blocking layer 141 may be formed of naphthalene-tetracarboxylic acid dianhydride (NTCDA). However, the present invention is not limited thereto. The hole blocking layer 141 may be 10 to 1,000 nm thick.

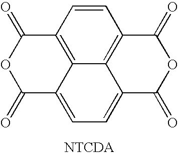

Although it is not shown in the drawings, an electron blocking layer for preventing the movement of electrons may be further formed between the anode 110 and the p-type substance layer 131. A hole transporting layer (not shown) for facilitating the transport of holes may be further formed between the p-type substance layer 131 and the electron blocking layer. An electron transporting layer (not shown) for facilitating the transport of electrons may be further formed between the n-type substance layer 132 and the hole blocking layer.

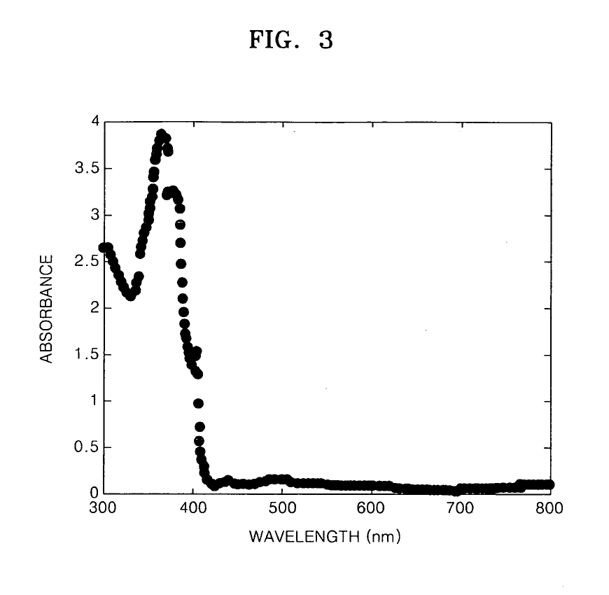

FIG. 3 is a plot showing the absorption spectrum of an organic photoelectric conversion film in the photoelectric conversion device according to an embodiment of the present invention. The photoelectric conversion device has a structure in which the p-type substance layer (rubrene), the n-type substance layer (C60 fullerene), and the hole blocking layer (NTCDA) are sequentially deposited between the anode 110 and the cathode 120 as shown in FIG. 1. Referring to FIG. 3, in the photoelectric conversion device according to the present embodiment, it can be seen that the organic photoelectric conversion film 130 has a characteristic of absorbing the wavelength of a blue light ray.

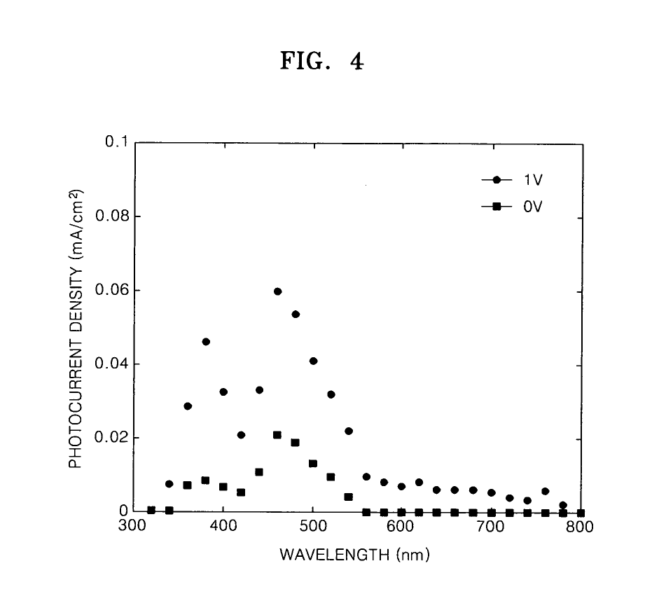

FIG. 4 is a plot showing a photocurrent density according to the wavelength of light in the photoelectric conversion device according to an embodiment of the present invention when a bias voltage is 0 V or 1 V. Referring to FIG. 4, it can be seen that, in the photoelectric conversion device according to the present embodiment, current may be generated by selectively absorbing the wavelength (350 to 540 nm) of a blue light ray of the solar light. Also, the photocurrent density increases as an applied bias voltage increases.

Accordingly, the photoelectric conversion device according to the present embodiment generates current by selectively absorbing only the wavelength of a blue light ray of the solar light by configuring the organic photoelectric conversion film 130 with the p-type substance layer 131 including rubrene and the n-type substance layer 132 including fullerene or fullerene derivative.

Thus, when a CMOS image sensor is manufactured by using the photoelectric conversion device according to the above-describe embodiment, the roles of the color filter, the microlens, and the photodiode may be substitutionally performed by the organic photoelectric conversion film. Therefore, a high quality CMOS image sensor may be manufactured in a simple process.

FIG. 2 is a cross-sectional view of a photoelectric conversion device according to another embodiment of the present invention. The following description focuses on differences from the above-described embodiment of FIG. 1. Referring to FIG. 2, a photoelectric conversion device according to the present embodiment includes the anode 110, the cathode 120, and an organic photoelectric conversion film 130′ that is formed between the anode 110 and the cathode 120 which are separated a predetermined distance from each other.

In the present embodiment, the organic photoelectric conversion film 130′ includes the p-type substance layer 131 formed on the anode 110, a co-deposition layer 133 formed on the p-type substance layer 131, and the n-type substance layer 132 formed on the co-deposition layer 133. Here, as in the above-described embodiment, rubrene is used as the p-type substance while fullerene or fullerene derivative is used as the n-type substance.

Also, in the present embodiment, the co-deposition layer 133 is formed of substance including fullerene (or fullerene derivative) and rubrene. The co-deposition layer 133 may be formed by co-depositing fullerene (or fullerene derivative) and rubrene on the p-type substance layer 131 formed of rubrene. As described above, C60 fullerene may be used as the fullerene. C70 fullerene, C76 fullerene, C78 fullerene, or C80 fullerene, for example, may be used as the fullerene derivative. In the present embodiment, the organic photoelectric conversion film 130′ has a p-i-n junction structure. Thus, as described above, the organic photoelectric conversion film 130′ may generate current by selectively absorbing the wavelength of a blue light ray like the organic photoelectric conversion film 130 of the above-described embodiment of FIG. 1.

The hole blocking layer 141 may be formed between the cathode 120 and the n-type substance layer 132 and may be formed of NTCDA, for example.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. An organic photoelectric conversion film comprising:
a p-type substance layer comprising rubrene; and
an n-type substance layer formed on the p-type substance layer, the n-type substance comprising fullerene or fullerene derivative.

2. The organic photoelectric conversion film of claim 1, further comprising a co-deposition layer formed between the p-type substance layer and the n-type substance layer, the co-deposition layer comprised of the material of the p-type substance layer and the material of the n-type substance layer.

3. The organic photoelectric conversion film of claim 1, wherein the fullerene is C60 fullerene.

4. The organic photoelectric conversion film of claim 1, wherein each of the p-type and n-type substance layers has a thickness of 5 to 300 nm.

5. The organic photoelectric conversion film of claim 1, capable of generating current by selectively absorbing the wavelength of a blue light ray.

6. An organic photoelectric conversion film, comprising:
a p-type substance layer comprising rubrene; and
an n-type substance layer formed on the p-type substance layer, the n-type substance formed of at least one material selected from the group consisting of C60 fullerene, C70 fullerene, C76 fullerene, C78 fullerene, and C80 fullerene.

7. The organic photoelectric conversion film of claim 6, further comprising a co-deposition layer between the p-type substance layer and the n-type substance layer, the co-deposition layer formed by co-depositing rubrene and said at least one material.

8. The organic photoelectric conversion film of claim 6, wherein said at least one material is C60 fullerene.

9. An image sensor having the organic photoelectric conversion film of claim 6.

10. A photoelectric conversion device, comprising:
an anode;
a cathode; and
an organic photoelectric conversion film formed between the anode and the cathode, the organic photoelectric conversion film comprising:
a p-type substance layer formed on the anode, the p-type substance layer comprising rubrene; and
an n-type substance layer formed on the p-type substance layer, the n-type substance layer comprising fullerene or fullerene derivative.

11. The photoelectric conversion device of claim 10, wherein the organic photoelectric conversion film further comprises a co-deposition layer formed between the p-type substance layer and the n-type substance layer, and the co-deposition layer is comprised of the material of the p-type substance layer and the material of the n-type substance layer.

12. The photoelectric conversion device of claim 11, wherein the n-type substance layer comprises C60 fullerene.

13. The photoelectric conversion device of claim 11, wherein each of the p-type and n-type substance layers has a thickness of 5 to 300 nm.

14. The photoelectric conversion device of claim 11, wherein the organic photoelectric conversion film is capable of generating current by selectively absorbing the wavelength of a blue light ray.

15. The photoelectric conversion device of claim 11, further comprising a hole blocking layer formed between the cathode and the n-type substance layer.

16. The photoelectric conversion device of claim 15, wherein the hole blocking layer is formed of naphthalene-tetracarboxylic acid dianhydride.

17. The photoelectric conversion device of claim 15, wherein the hole blocking layer has a thickness of 10 to 1,000 nm.

18. The photoelectric conversion device of claim 11, further comprising an electron blocking layer formed between the anode and the p-type substance layer.

19. The photoelectric conversion device of claim 11, wherein the anode is formed of a transparent conductive material.

20. The photoelectric conversion device of claim 11, wherein the cathode is formed of a transparent conductive material or metal.
